(19) United States
(12) Patent Application Publication
(10) Pub. No.: US 2023/0109695 A1
(43) Pub. Date: Apr. 13, 2023

(54) ENERGY BAND-PASS FILTERING FOR IMPROVED HIGH LANDING ENERGY BACKSCATTERED CHARGED PARTICLE IMAGE RESOLUTION

(71) Applicant: ASML Netherlands B.V., Veldhoven (NL)

(72) Inventors: Xuechen ZHU, San Jose, CA (US); Farshid TAZESH, San Jose, CA (US); Datong ZHANG, San Jose, CA (US); Weiming REN, San Jose, CA (US)

(73) Assignee: ASML Netherlands B.V., Veldhoven (NL)

(21) Appl. No.: 17/964,783

(22) Filed: Oct. 12, 2022

Related U.S. Application Data
(60) Provisional application No. 63/254,838, filed on Oct. 12, 2021.

(51) Int. Cl. H01J 37/244; H01J 37/22; H01J 37/28; H01J 37/05

(52) U.S. Cl. CPC H01J 37/244; H01J 37/222; H01J 37/28; H01J 37/05; H01J 2237/2448; H01J 2237/057; H01J 2237/24475

(57) ABSTRACT

Some embodiments are related to a method of or apparatus for forming an image of a buried structure that includes: emitting primary charged particles from a source; receiving a plurality of secondary charged particles from a sample; and forming an image based on received secondary charged particles that have an energy within a first range.

### FIELD

The description herein relates to detectors and detection methods, and more particularly, to detectors and detection methods that may be applicable to charged particle detection.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided as dedicated tools for this purpose.

With continuing miniaturization of semiconductor devices, performance demands for inspection systems, including detectors, may continue to increase. For example, electron beam (E-beam) systems with high landing energy (LE) capabilities, e.g., 30 keV and beyond, have attracted great interest as a result of the increasing aspect ratio of vertical structures that may be used in memory devices, as well as continuously shrinking design rules that may require more stringent overlay performance in DRAM and logic devices. High LE systems show great potential in applications such as trench/hole bottom inspection, buried defect/void detection, and overlay/see-through metrology, etc. due to the strong penetration capability of primary electrons (PEs) and the large momentum of backscattered electrons (BSEs) that may allow BSEs to escape the sample material and reach the detector. However, the large amount of energy of PEs in such systems may lead to a much larger interaction volume in the sample and may cause degraded imaging quality.

### SUMMARY

Embodiments of the present disclosure provide systems and methods for detection based on charged particle beams. In some embodiments, there may be provided a charged particle beam system configured to perform detection of a sample. A method of detection may include detecting charged particles emitted from a sample. A method of forming an image of a buried structure may includes: emitting primary charged particles from a source; receiving a plurality of secondary charged particles from a sample; and forming an image based on received secondary charged particles that have an energy within a first range.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIG. 2A and FIG. 2B are diagrams illustrating a charged particle beam apparatus that may be an example of an electron beam tool, consistent with embodiments of the present disclosure.

FIG. 3 is a diagrammatic representation of a substrate that may be used for wafer inspection, consistent with embodiments of the present disclosure.

FIG. 4 is a diagrammatic representation of collection of secondary particles emitted from a sample, consistent with embodiments of the present disclosure

FIG. 5 illustrates a sensing element that may make up part of a detector, consistent with embodiments of the disclosure.

FIG. 6 is a graph of detection signal intensity plotted against time, consistent with embodiments of the disclosure.

FIG. 7A illustrates BSE detection with low landing energy, consistent with embodiments of the disclosure.

FIG. 7B illustrates BSE detection with high landing energy, consistent with embodiments of the disclosure.

FIG. 8 is a graph of BSE yield plotted against distance along the x-direction of a sample, consistent with embodiments of the disclosure.

FIG. 9A and FIG. 9B illustrate a relationship between penetration depth and energy of charged particles is a flowchart illustrating a method of determining an overlay measurement, consistent with embodiments of the disclosure.

FIGS. 10A-10E illustrate BSE detection for a first landing energy, consistent with embodiments of the disclosure.

FIGS. 11A-11E illustrate BSE detection for a second landing energy, consistent with embodiments of the disclosure.

FIG. 12A and FIG. 12B illustrate correspondence relationships between BSE emission energy, BSE collection yield, and primary electron landing energy, consistent with embodiments of the disclosure.

FIG. 13 is a flowchart illustrates a method of determining an overlay measurement, consistent with embodiments of the disclosure.

FIG. 14 is a flowchart illustrates a method of determining an overlay measurement, consistent with embodiments of the disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

A SEM image may be made up of pixels that correspond to locations irradiated by a primary electron beam as the beam scans across the surface of a sample in, e.g., a raster pattern. A higher resolution of pixels (e.g., the number of individual pixels that make up the image) typically corresponds to higher image quality. The more pixels there are, the finer the detail in the image As structures of interest in ICs become smaller and smaller, it may be more important to produce SEM images with higher resolution to accurately observe structures. However, when a primary electron beam with high landing energy (LE) is used, resolution may be negatively affected.

In some applications, it may be desirable to use high landing energy in a SEM system. The electron source of the SEM may generate a primary electron beam with high LE that is projected onto the sample. High energy electrons may be useful for imaging because they can penetrate deeper into the material of the sample and can reveal additional information about the sample. High LE SEM systems may enable or enhance performance of inspections of the bottom of trenches or holes, detection of buried features such as defects or voids, and performing overlay metrology (e.g., analyzing the alignment of stacked structures). However, the higher energy of the electrons in the primary electron beam means that the electrons may interact with a relatively large volume of material of the sample upon impinging the sample (i.e., the “interaction volume”). Although high energy electrons may penetrate deeper, they may also scatter in other random directions before exiting the material of the sample. Because pixels may be used to form a 2-dimensional map, and electrons may disperse in side-to-side directions, such scattering may cause problems in imaging resolution.

As explained above, a SEM image may be formed of pixels. As a primary beam of a SEM scans across a sample, secondary particles, such as secondary electrons (SEs) and backscattered electrons (BSEs) may be detected by a detector, and information gathered therefrom may be used for forming each pixel in the image. However, with higher LE, the interaction volume in the sample may be increased. The increase in interaction volume may encompass lateral regions (e.g., regions to the sides in the 2-dimensional plane that defines the image consisting of pixels). Pixels may be formed based on information from detected electrons, but information from neighboring pixels may overlap. For example, the detected electrons corresponding to one pixel may include information relating to structures that would be more appropriately located in neighboring pixels. Such effects may cause the SEM image to have poor resolution, and the resulting image may be blurry.

Some embodiments of the disclosure may provide systems and methods for detecting charged particles, such as electrons, based on their energy. There may be a correlation between energy of secondary charged particles arriving at a detector and their penetration depth in a sample. A relationship between energy and depth may be used to filter out or isolate electrons that correspond to particular regions of the sample. Certain regions may be targeted so as to enhance resolution of a formed image. For example, a neck region in an interaction volume may have a relatively narrow width. In comparison, a bulb region in the interaction volume may have a relatively wide width that may overlap with adjacent pixels. Electrons coming from the neck region may be used to form a pixel in an image, and the image may have enhanced resolution. Techniques similar to band-pass filtering may be used.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing systems and methods in systems utilizing electron beams (“e-beams”). However, the disclosure is not so limited. Other types of charged particle beams may be similarly applied. Furthermore, systems and methods for wafer inspection or overlay measurement may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

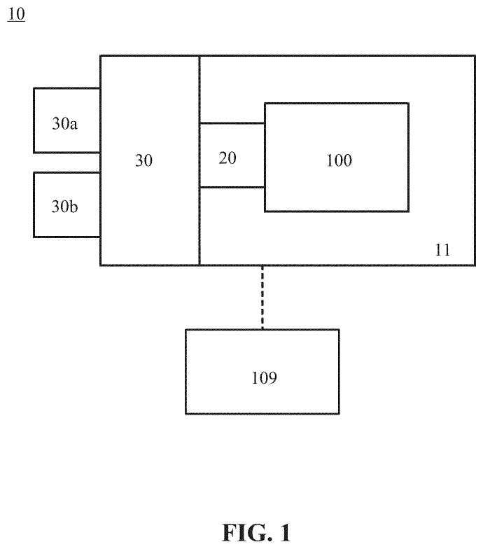

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a sample (e.g., a wafer) under inspection. The interactions of the primary electrons with the wafer may result in secondary particle beams being formed. The secondary particle beams may comprise backscattered electrons (BSEs), secondary electrons (SEs), or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity or other parameters of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer. The detector may include an energy-discriminating detector. The detector may be configured to count and characterize individual electron arrival events. Examples of detectors are given in U.S. Publication No. 2019/0378682, which is incorporated by reference in its entirety.

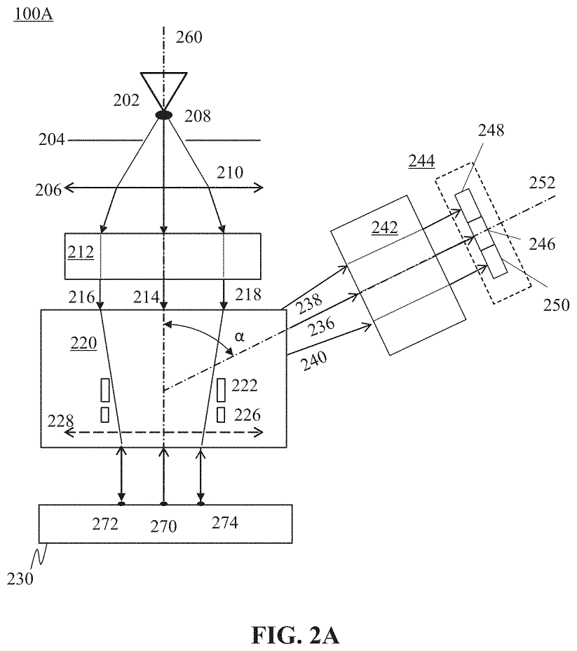

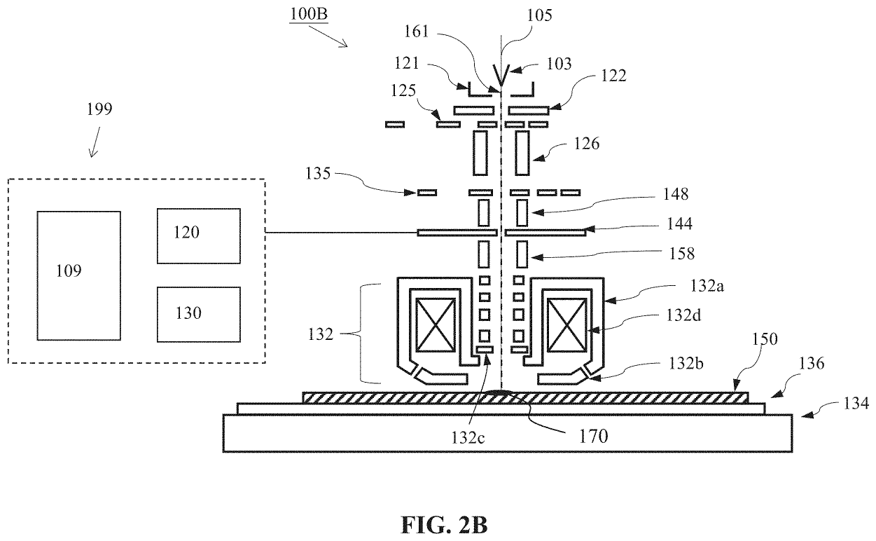

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle a toward an electron detection device 244, as shown in FIG. 2A.

A detector in a charged particle beam system may include one or more sensing elements. The detector may comprise a single-element detector or an array with multiple sensing elements. The sensing elements may be configured to detect charged particles in various ways. The sensing elements may be configured for charged particle counting. Sensing elements of a detector that may be useful for charged particle counting are discussed in U.S. Publication No. 2019/0378682, which is incorporated by reference in its entirety. In some embodiments, sensing elements may be configured for signal level intensity detection.

Sensing elements may include a diode or an element similar to a diode that may convert incident energy into a measurable signal. For example, sensing elements in a detector may include a PIN diode. Throughout this disclosure, sensing elements may be represented as a diode, for example in certain figures, although sensing elements or other components may deviate from ideal circuit behavior of electrical elements such as diodes, resistors, capacitors, etc.

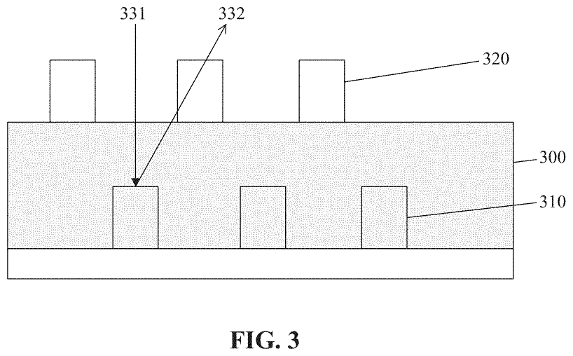

FIG. 3 illustrates an exemplary structure of a substrate 300, consistent with embodiments of the present disclosure. Substrate 300 may be a target that may be useful for performing overlay measurement.

Measuring relative displacements of structures on a chip is a common task in the semiconductor industry. An electronic circuit may be built up on a wafer from many different layers that should be stacked on top of each other very accurately to assure a correctly functioning chip. Layer placement may be monitored by dedicated wafer overlay metrology systems. Such systems may measure the relative displacement (e.g., “overlay error”) between two functional layers on the wafer by comparing dedicated targets included in both layers. In a lithographic process, parameters of targets or other structures may be monitored so that feed-back or feed-forward control may be performed to align layers and form patterned features accurately.

As shown in FIG. 3, some structures in an overlay target may be buried in a wafer, for example, below insulator films. Substrate 300 includes first grating 310 formed in a first layer and second grating 320 formed in a second layer. In some embodiments, further gratings or other structures in further layers may also be provided.

Features of interest may be buried at various depths in a sample. Different types of signal electrons may be useful for detecting different types of features. For example, a primary beam may irradiate a sample and signal electrons including secondary electrons (SEs) and backscattered electrons (BSEs) may be emitted from the sample at the irradiated area. BSEs may penetrate to a relatively deeper depth in a sample and may have relatively higher energy so as to escape the material of the sample and reach a detector. Thus, BSEs may be useful to detect buried structures. As shown in FIG. 3, primary beam 331 may irradiate substrate 300, and BSEs 332 may be directed to a detector. BSEs 332 may indicate information of first grating 310 or second grating 320.

Determining an overlay measurement may involve detecting signals from different layers of a sample. In some embodiments, separation of signals from different layers of the sample may be achieved by (i) energy-sensitive detection, or (ii) imaging with beams of different landing energy (LE).

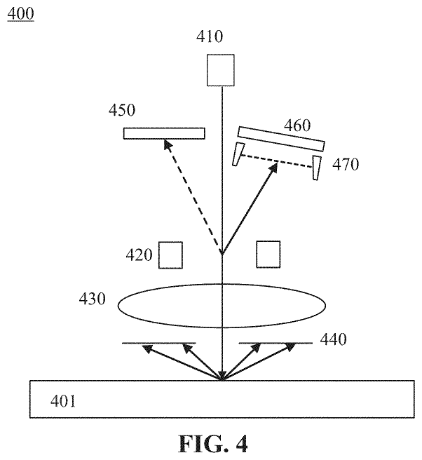

Reference is now made to FIG. 4, which illustrates the collection of secondary particles, consistent with embodiments of the disclosure. A charged particle beam system 400 may be configured to inspect a wafer 401. System 400 include a charged particle beam source 410, a beam separator 420, an objective 430, a first detector 440, a second detector 450, and a third detector 460. Objective 430 may include an objective lens. First detector 440 may include a bottom backscattered electron detector (BBD). Second detector 450 may include a SE detector. Third detector 460 may include a BSE detector. Second detector 450 or third detector 460 may include an energy filter 470. Energy filter 470 may be energized by a power source and may be configured to attract electrons. For example, a voltage may be applied to energy filter 470 so that electrons having energy less than a threshold may be attracted to energy filter 470, and only electrons having energy greater than or equal to the threshold may pass on to reach third detector 460. Energy filter 470 may act as a high pass filter. In some embodiments, hardware may also be provided to implement a low pass filter or other types of filters. For example, electrons may be deflected by a dispersion device so that electrons of a certain energy are directed to a detector.

Beam separator 420 may include a Wein filter. Beam separator 420 may be configured to allow electrons from the primary beam generated by beam source 410 to travel straight through without being deflected, while signal electrons traveling from wafer 490 to beam separator 420 are deflected differently according to their parameters. For example, SEs, having relatively low energy may be directed to second detector 450 while BSEs, having relatively high energy may be directed to third detector 460. Energy filter 470 may allow for further selection of electrons of interest. Using energy filter 470, BSEs of certain energies may be detected by third detector 460.

First detector 440 may be provided in addition to or alternatively to second detector 450 or third detector 460. First detector 440 may be arranged between objective 430 and wafer 401. First detector 440 may be configured to collect a substantially all signal electrons emitted from wafer 401. First detector 440 may be configured to discriminate electrons based on their energy.

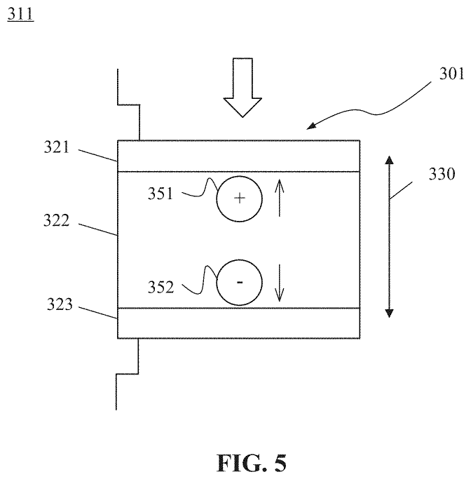

Reference is now made to FIG. 5, which illustrates a sensing element that may make up part of a detector, consistent with embodiments of the disclosure. As shown in FIG. 5, a sensing element 311 may include a semiconductor structure of a p-type layer 321, an intrinsic layer 322, and an n-type layer 323. Sensing element 311 may include two terminals, such as an anode and a cathode. Sensing element 311 may be reverse biased, and a depletion region 330 may form and may span part of the length of p-type layer 321, substantially the entire length of intrinsic layer 322, and part of the length of n-type layer 323. In depletion region 330, charge carriers may be removed, and new charge carriers generated in depletion region 330 may be swept away according to their charge. For example, when an incoming charged particle reaches sensor surface 301, electron-hole pairs may be created, and a hole 351 may be attracted toward p-type layer 321 while an electron 352 may be attracted toward n-type layer 323. In some embodiments, a protection layer may be provided on sensor surface 301. The number of electron-hole pairs excited by an incoming electron may be proportional to the kinetic energy of the incoming electron. The kinetic energy of the incoming electron may be based on its emission kinetic energy from the sample.

A BSE beam may be projected onto a detector with a relatively low current density. For example, BSEs may be emitted from a sample that is irradiated by a primary beam in a relatively large area compared to the spot size of the primary beam on the sample. The detector may be an array detector comprising a plurality of sensing elements. Thus, the average electron arrival rate at any one sensing element in the detector may be relatively low so that individual electron arrival events can be easily discriminated. An incoming electron arriving at a sensing element in the detector may generate a current pulse due to the flow of numerous electron-hole pairs generated in response to the incoming electron arrival event at the sensing element. The intensity of the current pulse may correspond to the emission kinetic energy of the incoming electron. The detector may be configured to discriminate the incoming current pulse. For example, circuitry may be provided to perform energy analysis of BSEs based on multiple thresholds.

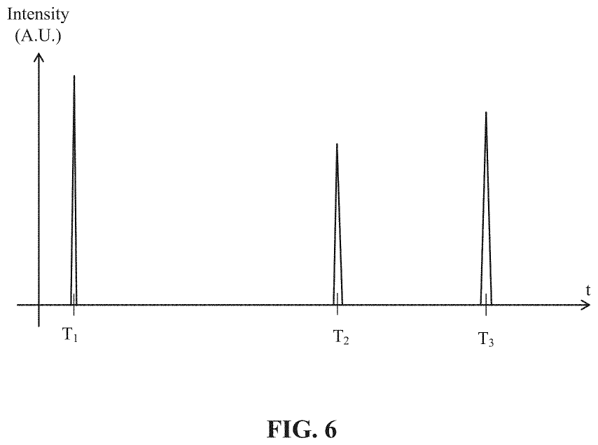

As shown in FIG. 6, a sensing element and circuit may output a detection signal on the basis of time. FIG. 6 is a graph of detection signal intensity in arbitrary units on the ordinate axis plotted against time on the abscissa axis. Charged particle arrival events at a sensing element may occur at time points T₁, T₂, and T₃. A detector may have sensing elements and a circuit configured to detect charged particle arrival events. For example, a sensing element may be configured to generate a signal pulse in response to an incident charged particle arriving at the sensing element, which may be due to the generation of electron-hole pairs in the sensing element, and which may be fed to a circuit. The circuit may record a charged particle arrival event upon determining that a charged particle has arrived at the sensing element. The circuit may also determine a level of energy associated with the charged particle arrival event.

In comparative embodiments, either an energy filter may be used with a main detector to suppress an SE signal that may have overwhelmed the BSE signal, or a dedicated BBD may be applied specifically for BSE detection that may enable production of an overall stronger BSE signal. Packaging constraints may prevent installation of an energy filter in front of a BBD because the BBD may be placed directly above a sample. In either comparative embodiment, the detection method will attempt to collect as many BSEs as possible without any further energy discrimination. In contrast, some embodiments of the disclosure may employ further energy discrimination, such as by using circuitry to perform energy analysis processing with multiple thresholds or by using multiple energy filters to enable energy filtering.

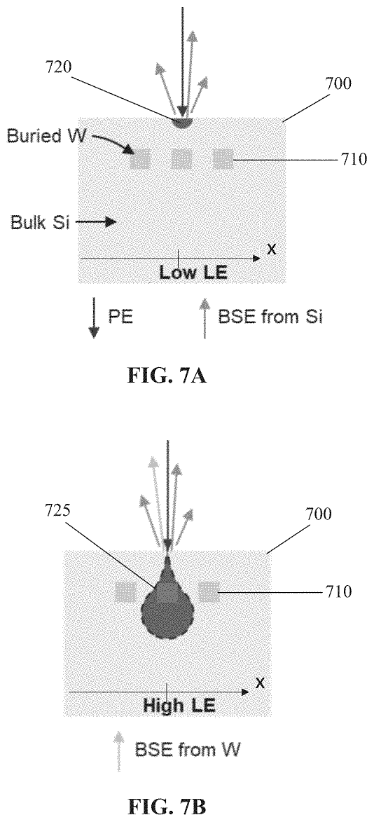

Regardless of the detection technology being used, there may exist a fundamental limitation in SEM imaging employing high landing energy (LE) that the strong energy of primary electrons (PEs) from the primary beam generated by the charged particle source leads to a much larger interaction volume as compared to low LE imaging. Information collected from each pixel may not necessarily only come from the particular feature of interest that may be targeted, such as a defect of interest (DOI), but the information will also inevitably contain signals from nearby structures (e.g., non-DOI structures). Therefore, a comparative imaging method may end up with an image having poor resolution. Such limitations are reflected in FIG. 7A and FIG. 7B.

FIG. 7A illustrates BSE detection with low landing energy. As shown in FIG. 7A, a substrate 700 may include a plurality of buried features 710. One or more of features 710 may be a DOI. Features 710 may include tungsten (W) implants. Features 710 may be surrounded by bulk material of substrate 700 that may include silicon. Primary electrons (PEs) from the primary electron beam may irradiate substrate 700, and interaction region 720 may be formed. Due to the low landing energy of the PEs, there may be only shallow penetration depth of interaction region 720. Interaction region 720 may not reach features 710, and so there may be no signal electrons emitted that come from features 710.

FIG. 7B illustrates BSE detection with high landing energy. As shown in FIG. 7B, PEs may have relatively high landing energy and a relatively large interaction region 725 may be formed. Interaction region 725 may have a teardrop shape. The teardrop shape of interaction region 725 may include a relatively narrow neck portion at its top and a relatively wide bulb portion at its bottom. Interaction region 725 may have a large volume that includes more features than a particular feature of interest. For example, electrons emitted from substrate 700 may include a small portion of electrons from a central one of features 710 and may include a large portion of electrons from the bulk material of substrate 700. In some cases, interaction region 725 may be so large as to include adjacent ones of features 710.

In a SEM system, a primary electron beam may scan across the surface of a sample. As shown in FIG. 7A and FIG. 7B, PEs may be projected onto substrate 700 at different locations in the x-direction. The primary electron beam may gradually move across the surface of substrate 700 in the positive x-direction. As the primary electron beam scans, the corresponding interaction region in substrate 700 may move with it. At any given point, the bulb portion of a large-volume interaction region may be wider than the irradiated area (beam spot) on the surface of substrate 700. Signal electrons detected at such point may contain information of structures not directly below the beam spot. Thus, imaging resolution may be poor. For example, it may be important to detect the leading edge of features 710 as the primary beam scans across substrate 700. However, if interaction region 725 includes a large bulb region encompassing features other than features 710, it may be difficult to detect the beginning of a feature among features 710 as a sharp edge.

FIG. 8 illustrates a graph of BSE yield plotted against distance along the x-direction of the substrate. The graph of FIG. 8 may correspond to detection results from a primary beam having high LE, such as that of FIG. 7B. As shown in FIG. 8, there may be relatively low contrast between peaks and troughs of the graph, which may represent the presence or absence of features 710 in the inspection region. The relatively low contrast of peaks may be the result of large amounts of overlap between signal electrons from features 710 (e.g., tungsten), and those from bulk material of the inspected sample (e.g., silicon). In other words, there may be poor contrast between locations above buried tungsten (e.g., DOI), and locations on silicon only (e.g., non-DOI).

The large bulb region of the teardrop shape of the interaction region produced by high LE charged particles may complicate inspection of buried structures. In some applications, features that are typically searched for may be on the order of lOs of nanometers. For example, x-y dimensions of features may be approximately 50 nm, 30 nm, or less. Meanwhile, the depth of the features in the inspected sample may be on the order of 100s of nanometers. For example, depth of features below the sample surface in the z-direction may be 100 nm, 200 nm, or greater. The landing energy of charged particles having sufficient energy to penetrate deep enough in the sample to detect such features may be such that a large bulb region forms. For example, to penetrate at least 100 nm into the sample surface, the width of a bulb region of an interaction volume may be larger than 30-50 nm. Thus, it may be difficult to accurately manipulate the beam energy in order to match the shape of the features that are desired to be observed.

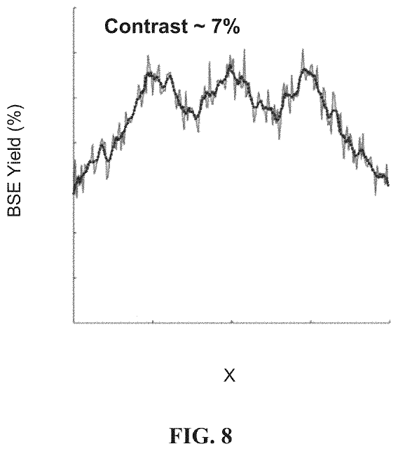

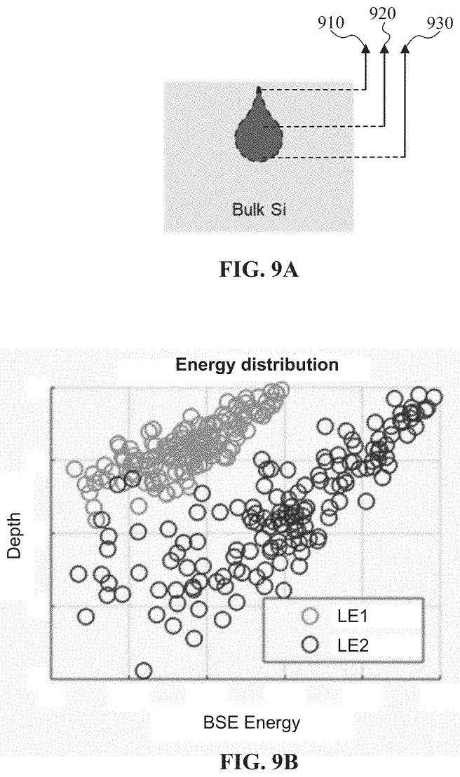

Reference is now made to FIG. 9A and FIG. 9B, which illustrate a relationship between penetration depth and energy of charged particles, consistent with embodiments of the disclosure. Charged particles, such as electrons, projected onto a sample may interact with the material of the sample. Some types of electrons may experience collisions with atoms of the material making up the sample and may be emitted back towards a detector. Electrons undergoing inelastic collisions may lose energy with each collision. An electron's penetration through the sample may be correlated with the number of collisions it experiences, and how much energy it retains. Thus, a relationship may be found that relates penetration depth of electrons to their energy. Electrons arriving at a detector with higher energy may have penetrated less into the sample. On the other hand, electrons arriving at the detector with lower energy may have penetrated deeper into the sample.

FIG. 9A is a diagrammatic representation of a relationship between energy of electrons and their penetration depth within an interaction volume in a sample. The electrons may be backscattered electrons (BSEs). The energy of the BSEs may be their emission energy as they are emitted from the sample. As shown in FIG. 9A, higher energy BSEs (e.g., those having higher energy when arriving at a detector) may have penetrated less into the sample. These BSEs may have interacted with only a very small portion of the material in the interaction volume, and thus do not contain information of other extraneous portions. Higher energy BSEs may correspond to regions near the surface and neck region of the interaction volume. Medium energy BSEs may have penetrated near a middle of a bulb region of the interaction volume. Lower energy BSEs may have penetrated to the bottom of the bulb region of the interaction volume. Medium and lower energy BSEs may have interacted with more portions of the interaction volume, and thus may be tainted by material outside the DOI. In some embodiments, it is desirable to remove the effect of such BSEs.

In some embodiments of the disclosure, investigations have revealed a strong correlation between trajectory depth and BSE energy. In other words, BSE signals with higher or lower energy can be found to be coming from a relatively shallower or deeper location inside a sample's material, respectively. For example, as shown in FIG. 9B, there may be a correlation between BSE energy and penetration depth. FIG. 9B may represent depth of an electron's penetration into a sample, such as bulk silicon, versus the electron's emission energy (from the sample) for various values of LE. Two data series may be represented in FIG. 9B, namely electrons beginning with a first landing energy LE1 and those beginning with a second energy LE2. Second landing energy LE2 may be greater than first landing energy LE1. Combining an BSE energy-depth relation with an understanding of the interaction volume, a BSE energy band-pass filtering strategy may be provided. Energy band-pass filtering may enable users to filter out BSEs that do not carry DOI information and may improve detection resolution.

Furthermore, tuning of the energy band-pass filtering may be used to further refine detection results so as to match a target depth of a feature. An energy range of electrons arriving at a detector may be determined that corresponds to a target depth of a feature to be observed. Energy filtering may be used to obtain information from only those electrons within the energy range. The information may be representative of the feature at the target depth. Thus, extraneous information may be filtered out.

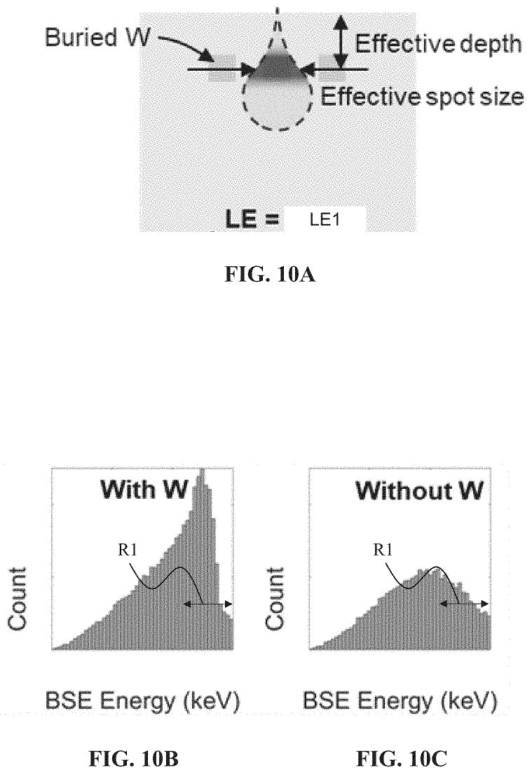

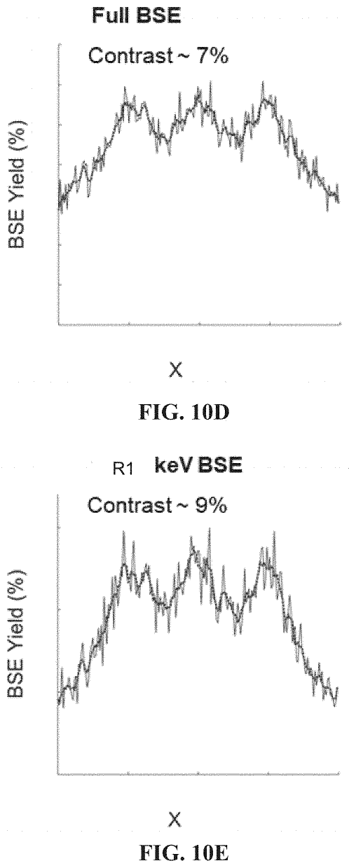

In some embodiments, a target feature may be embedded in a sample. FIG. 10A shows a primary electron beam applied to a substrate with buried tungsten features. To detect a target feature, it may be desirable to use backscattered electrons (BSEs) of a certain energy range. The energy range of BSEs may be selected so as to correspond to a narrow neck region in an interaction volume. The energy range may be tuned so as to capture information of the target feature and disregard information of other features.

For example, when a tungsten target with finite size and depth is added into a bulk silicon sample, it may be found that the additional BSE signal coming from the tungsten target would mostly be found within a narrow energy range. As shown in FIGS. 10A-10C, a spike in detected electrons may be found in a particular range of BSE energy. FIG. 10B and FIG. 10C show that the energy distribution of BSEs is significantly different depending on whether tungsten is present in the sample or not. The particular range of BSE energy where a difference is elucidated may correspond to the depth of the tungsten target based on an energy-depth relationship. Energy filtering may be used to select BSE signals from a specific effective depth that matches the depth of the target feature while disregarding signals from other depths. Signals from other depths may correspond to only bulk material of the sample. As shown in FIG. 10B and FIG. 10C, there may be a range R1 of energy of electrons emitted from the sample that may be configured as an effective detection range. Range R1 may be from a first energy level (e.g., lower limit) to a second energy level (e.g., upper limit) The first energy level may correspond to a top of the target feature and the second energy level may correspond to the bottom of the target feature. Electrons detected having energy within range R1 may be determined to have come from a particular depth range of the sample.

FIG. 10D illustrates a graph of BSE yield plotted against distance along the surface of the sample in the x-direction, consistent with embodiments of the disclosure. The graph of FIG. 10D may correspond to detection results from a primary beam having relatively high LE so that a bulb-shaped interaction volume may be formed in a sample, such as that of FIG. 10A. The BSE yield may be that of all electrons collected (i.e., with no energy filtering having taken place). As shown in FIG. 10D, there may be relatively low contrast between peaks and troughs of the graph, which may represent the presence or absence of features in the inspection region. The relatively low contrast of peaks may be the result of large amounts of overlap between signal electrons from target features and those from bulk material of the inspected sample.

FIG. 10E illustrates a graph of BSE yield with energy filtering plotted against distance along the surface of the sample in the x-direction, consistent with embodiments of the disclosure. The graph of FIG. 10E may correspond to detection results from the same primary beam as that of FIG. 10A. However, energy filtering may be used to filter electrons other than those of a specified energy range. The specified energy range may include range R1, discussed above with reference to FIG. 10B and FIG. 10C. As shown in FIG. 10E, there may be relatively higher contrast between peaks and troughs as compared to FIG. 10D. Energy filtering may be used to narrow down detection results to particular depths of the region of interest.

Energy filtering may be performed to analyze signals from electrons corresponding to a particular volume. A detector may be configured to receive electrons of any energy. However, the detector may also be configured to perform energy filtering. For example, the detector may include circuitry to compare the signal pulse generated by an electron arrival event at a sensing element to one or more thresholds, and determine the specific energy associated with the electron arrival event. General information of electron arrival events (e.g., time stamp, which may be used to correlate the information with a particular scanning location) and specific information of the electron arrival events (e.g., energy level), may be used to provide detection information with high precision. A high contrast between target features and non-target features may be achieved. Energy filtering may enhance charged particle imaging resolution.

In some embodiments, a detector may be provided with an energy filter configured to perform energy filtering. The energy filter may be provided between the sample and the detector. The energy filter may include one or more stages. Each of the stages may be configured to filter out electrons above or below a predetermined energy. For example, a high-pass filter may be provided that includes a mesh or screen to which a voltage is applied. Electrons having a predetermined energy or higher may have sufficient energy to pass through the mesh, while less energetic electrons are attracted to the mesh and immobilized. Each stage may be configured to function like a threshold. In some embodiments, a dispersion device may be used to deflect electrons differently based on their energy.

Moreover, in some embodiments, the effect of energy filtering may also be related to the primary beam LE used. If LE is below a certain amount, then the cross-section of the interaction volume at the selected depth (e.g., the “effective spot size”) may be too large relative to the target feature. For example, the effective spot size may be larger than the buried tungsten object, and collected electrons may represent signal from the surrounding silicon. To alleviate such effect, a higher LE may be used. Higher LE may be used to form an interaction volume with a narrower “neck” of the interaction volume at the region of interest. This may be due to the longer mean-free-path of the higher LE electrons. Although there may be a greater proportion of deeper penetrating electrons that may travel into the bulk material, the neck region where the feature of interest is located may be made smaller, and detection precision may be enhanced.

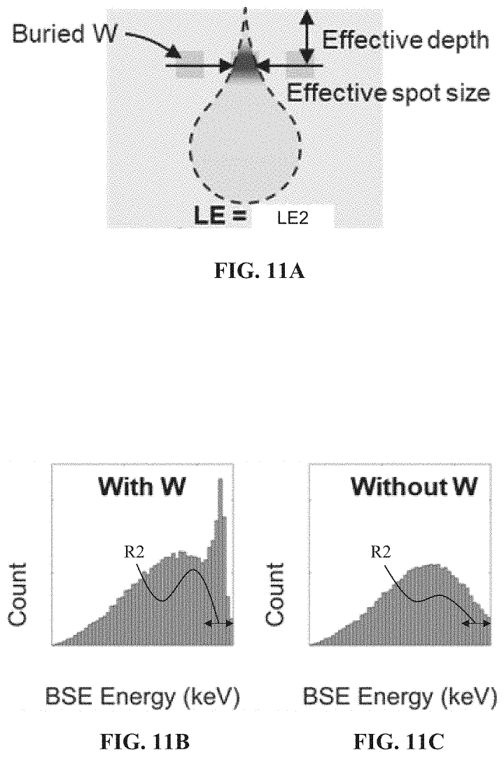

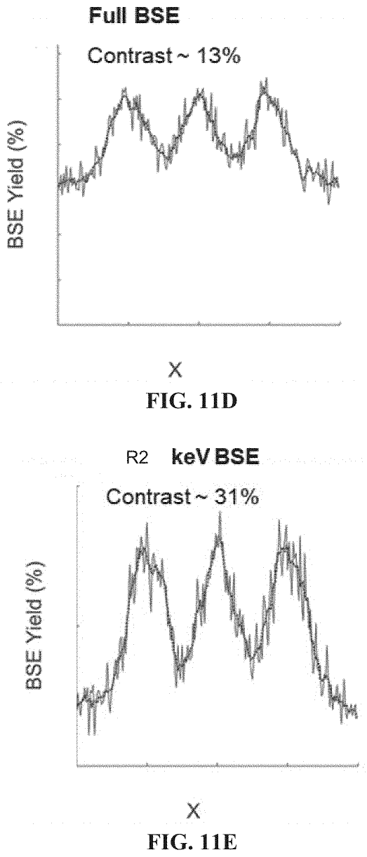

FIG. 11A, similar to FIG. 10A, shows a primary electron beam applied to a substrate with buried tungsten features. However, a higher LE beam may be used in FIG. 11A relative to that in FIG. 10A. A larger interaction volume may be formed, and the average penetration depth of electrons may be greater as compared to a lower LE case, such as that of FIG. 10A. However, as shown in FIG. 11A, in the region where the target features are found (e.g., where there is buried W), the effective spot size may be made smaller. Therefore, more or substantially all of the signal electrons selected as corresponding to this depth may be from the target feature.

FIG. 11B and FIG. 11C show that there may be a range R2 of energy of electrons emitted from the sample that may be configured as an effective detection range. Range R2 may be at a higher energy level than range R1, discussed above with reference to FIG. 10B and FIG. 10C. Range R2 may be from a first energy level (e.g., lower limit) to a second energy level (e.g., upper limit) The first energy level may correspond to a top of the target feature and the second energy level may correspond to the bottom of the target feature. Electrons detected having energy within range R2 may be determined to have come from a particular depth range of the sample.

FIG. 11D illustrates a graph of total BSE yield plotted against distance along the surface of the sample in the x-direction, consistent with embodiments of the disclosure. The graph of FIG. 11D may correspond to detection results from a primary beam having relatively high LE so that a bulb-shaped interaction volume may be formed in a sample, such as that of FIG. 11A. The BSE yield may be that of all electrons collected (i.e., with no energy filtering having taken place). As shown in FIG. 11D, although there may be greater contrast between peaks and troughs compared to a case of lower landing energy, such as that of FIG. 10D, there may still be potential for improvement. Further contrast may be achieved by performing energy filtering to select a target depth of the target feature. Energy filtering may reduce or eliminate the effects of overlap of signal electrons from target features and those from bulk material of the inspected sample.

FIG. 11E illustrates a graph of BSE yield with energy filtering plotted against distance along the surface of the sample in the x-direction, consistent with embodiments of the disclosure. The graph of FIG. 11E may correspond to detection results from the same primary beam as that of FIG. 11A. However, energy filtering may be used to filter electrons other than those of a specified energy range. The specified energy range may include range R2, discussed above with reference to FIG. 11B and FIG. 11C. As shown in FIG. 11E, there may be relatively higher contrast between peaks and troughs as compared to FIG. 11D.

Therefore, by adjusting LE with BSE energy filtering, a user may obtain the ability to choose the BSE signal with the desired effective depth and effective spot size. In some embodiments, a detection method may remove most non-DOI information and improve imaging resolution.

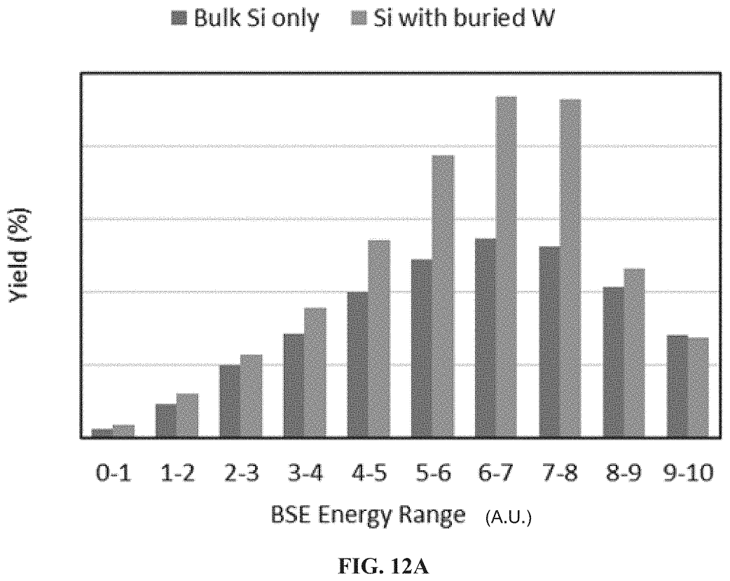

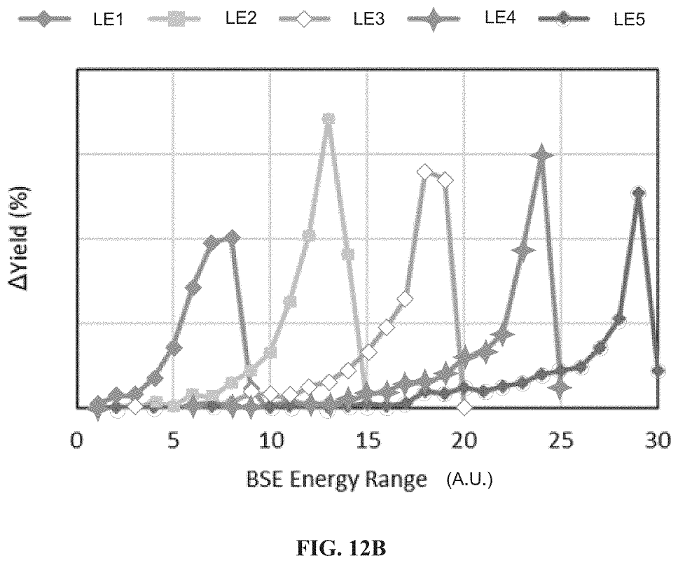

In some embodiments, there may be provided a process flow to determine the optimized BSE energy range with different LE. At any given LE, an operator may apply energy filtering through various energy ranges and find the resulting BSE yield at locations with and without a target features, such as a buried DOI. FIG. 12A illustrates a graph of total BSE yield for a particular LE plotted against detected electron energy. The x-axis of FIG. 12A may represent energy of detected BSEs in arbitrary units. A first data series may indicate detection results for a region of a sample with no buried DOI (e.g., only bulk silicon). A second data series may indicate detection results for a region of the sample with a buried DOI (e.g., with buried W). Then, the difference in yield (Δyield) may be determined. Regions where Δyield is the highest may indicate the optimum range for applying energy filtering.

Differences in yield may be determined for various LEs, and as a correlation of the energy ranges may be found. FIG. 12B illustrates plots of differences in BSE yield for various LEs (LE1 increasing through LES) with energy of detected BSEs on the x-axis. Based on such results, the optimal energy range to be used for filtering may be determined as a range where Δyield becomes the highest. Meanwhile when comparing different LEs with their optimized energy ranges filtered, using higher LE may provide a smaller “effective spot size” and thus better resolution, but may also have less BSE yield remaining after the energy filtering. Less yield may mean a weaker image signal. Thus, an optimizing method may take into account requirements for imaging signal strength. An optimization method may balance the needs of resolution versus signal strength when choosing the optimized LE.

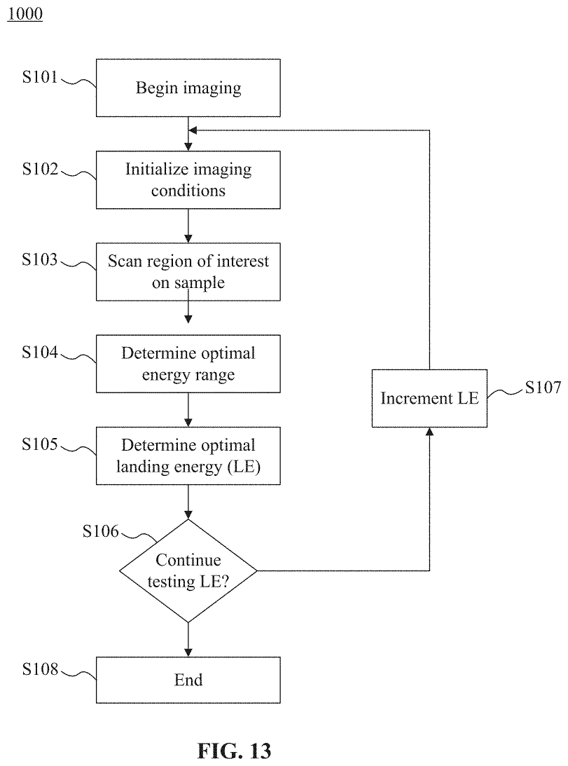

Reference is now made to FIG. 13, which illustrates a method of determining imaging conditions for charged particle beam imaging, consistent with embodiments of the disclosure. Charged particle beam imaging may include SEM imaging. As shown in FIG. 13, a method 1000 may begin with a step S101 of beginning imaging. Step S101 may include generating a charged particle beam using a charged particle beam source of a charged particle beam apparatus. The charged particle beam may be a primary beam of electrons. In some embodiments, the charged particle beam may include a plurality of electron beamlets.

Method 1000 may be performed by a processor of a charged particle beam apparatus. For example, controller 109, as discussed above with reference to FIG. 1 and FIG. 2B, may be used to perform method 1000.

Method 1000 may include a step S102 of initializing imaging conditions. Imaging conditions may include landing energy (LE) of primary electrons (PE) of the primary beam. Step S102 may include loading a previously used LE from memory. In some embodiments, an operator may specify a preferred starting LE.

Method 1000 may include a step S103 of scanning a region of interest on a sample. Step S103 may include using a deflector of the charged particle beam apparatus to scan the primary beam along the surface of the sample. While the primary beam is scanning across the sample, secondary charged particles may be detected at a detector. The secondary charged particles may include secondary electrons (SEs) or backscattered electrons (BSEs). The detector may detect the secondary charged particles without discriminating their energy. The detector may be configured to collect BSEs emitted from the sample.

The region of interest on the sample may include a region with a DOI and a region without a DOI. Step S103 may include scanning portions of the sample that have buried target features and portions that do not have buried target features. Differences in secondary charged particle yield may be determined from the different imaged regions. For example, Δyield may be determined as discussed above with reference to FIG. 12A. Also, differences in collected BSEs between regions with a target feature and those without may be found according to FIG. 10B and FIG. 10C, and FIG. 11B and FIG. 11C.

Method 1000 may include a step S104 of determining an optimal energy range. The optimal energy range may include a range of emission energy of collected secondary charged particles in which Δyield is determined to be highest, as discussed above with reference to FIG. 12A. In some embodiments, the optimal energy range may be found as R1 or R2, as discussed above with reference to FIG. 10B, FIG. 10C, FIG. 11B, and FIG. 11C.

Method 1000 may include a step S105 of determining an optimal landing energy (LE). The optimal LE may be determined based on requirements of resolution and signal strength. In some embodiments, method 1000 may be configured to cycle through different LEs and may determine to select the last-used LE as the optimal LE when its corresponding Δyield is found to be above a predetermined amount, or is found to be highest among determined Δyields, for example.

Method 1000 may include a step S106 of determining whether or not to continue testing LEs. Method 1000 may be configured to cycle through a predetermined range of different LEs to test. In some embodiments, method 1000 may be configured to test various LEs based on desired imaging characteristics or the sample to be inspected. Method 1000 may test different LEs exhaustively or may determine a best one among a plurality of those tested.

If it is determined to continue testing LEs in step S106, method 1000 may continue to a step S107 of incrementing LE. LE may be incremented by a certain amount, and method 1000 may return to step S103 of scanning the sample.

If it is determined to stop testing LEs in step S106, method 1000 may continue to a step S108 and the method may end.

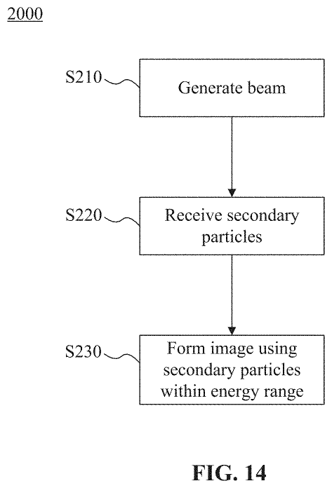

Reference is now made to FIG. 14, which illustrates a method of forming an image of a buried structure, consistent with embodiments of the disclosure. The image may be based on charged particle beam imaging. The method may be performed using a charged particle beam apparatus. As shown in FIG. 14, a method 2000 may begin with a step S210 of generating a charged particle beam using a charged particle beam source of a charged particle beam apparatus. The charged particle beam may be a primary beam of electrons. In some embodiments, the charged particle beam may include a plurality of electron beamlets. Step S210 may include emitting electrons from a source.

Method 2000 may include a step S220 of receiving a plurality of secondary charged particles from a sample. Step S220 may include detecting, by a detector of the charged particle beam apparatus, secondary charged particles emitted from the sample in response to incidence of the primary beam on the sample. The secondary charged particles may include backscattered electrons (BSEs). The BSEs may be emitted from the sample in response to the electrons of the primary beam interacting with the sample.

Method 2000 may include a step S230 of forming an image based on received secondary charged particles. Step S230 may include forming the image based on BSEs that have an energy within a predetermined energy range. Electrons may be received indiscriminately on a detector, and only some of the electrons may be used to form the image. Electrons corresponding to a target feature depth may be used to form the image. The electrons may be associated with an effective spot size and an effective depth.

Step S230 may include performing energy filtering. Step S230 may include filtering out or disregarding some electrons among all of the electrons that may be detected by the detector. The detector may be configured to perform energy filtering using included circuitry. In some embodiments, a processor or other component of computer hardware of the charged particle beam apparatus may be used to perform energy filtering.

In some embodiments, step S230 may include performing energy filtering using integrated circuitry of a detector. The detector may be configured to compare the energy of collected electrons to one or more thresholds and may forward on only those signals determined to be within the desired energy range. In some embodiments, step S230 may include performing energy filtering using an energy filter, such as a device that may be arranged in front of the detector that is configured to capture or divert some electrons while letting other electrons pass through to reach the detector.

In some embodiments, the energy range may be determined based on a correlation between energy levels of received BSEs and depth of penetration of primary electrons that form the BSEs.

In some embodiments, the energy range may be determined such that only electrons with a penetration depth below a threshold are utilized in forming the image.

In some embodiments, method 2000 may include determining optimal imaging conditions, such as by method 1000. For example, method 1000 may be performed to determine an optimal LE and an optimal energy range, and the optimal LE and energy range may be used to form an image according to method 2000.

Other methods consistent with embodiments of the disclosure may include a method of calibration, a method of determining an energy-depth relationship, a method of determining a correspondence ratio between penetration depth of primary electrons and emission energy of backscattered electrons, a method of modeling a substrate for determining an energy-depth relationship or forming an image, a method of performing overlay measurement, a method of determining optimal ranges for energy filtering, a method of charging a substrate using a charged particle beam device, and methods of manufacturing a target having buried features, and so on.

In some embodiments of the disclosure, systems and methods may be used to improve the resolution for detection of buried features (such as defects) or the measurement of see-through overlay. According to some embodiments, improvements of DOI/non-DOI contrast may be achieved in the range of 50%˜200%, depending on the size/depth of the DOI, and the LE used.

A non-transitory computer-readable medium may be provided that stores instructions for a processor of a controller (e.g., a central processing unit or electronic control unit that is configured to control a charged particle beam apparatus) for performing a method according to the exemplary flowcharts of FIG. 13 or FIG. 14 or other methods consistent with embodiments of the present disclosure. For example, the instructions stored in the non-transitory computer-readable medium may be executed by the circuitry of the controller for performing method 1000 or 2000 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:

1. A method of forming an image of a buried structure comprising:
emitting primary charged particles from a source;
receiving a plurality of secondary charged particles from a sample; and
forming an image based on received secondary charged particles that have an energy within a first range.
2. The method of clause 1, wherein the first range is determined based on a correlation between energy levels of received secondary charged particles and depth of penetration of the primary charged particles into the sample.
3. The method of clause 2, wherein the first range is determined such that only secondary charged particles with a penetration depth below a first threshold are used to form the image.
4. The method of clause 1, wherein the primary charged particles are electrons.
5. The method of clause 1, wherein the secondary charged particles are backscattered electrons.
6. The method of clause 1, further comprising:
performing energy filtering, wherein the energy filtering includes using signals from the secondary charged particles that have the energy within the first range.
7. The method of clause 6, wherein the energy filtering includes discarding signals from the secondary charged particles that have an energy outside the first range.
8. The method of clause 6, further comprising:
diverting or immobilizing secondary charged particles that have an energy outside the first range using an energy filter.
9. The method of clause 1, further comprising:
adjusting a landing energy of the primary charged particles based on a depth of the buried structure.
10. The method of clause 9, wherein the landing energy is adjusted so that an effective depth and an effective spot size of an interaction region formed by the primary charged particles is matched to the buried structure.
11. A method of determining imaging conditions for charged particle beam imaging, comprising:
scanning a primary charged particle beam across a region of a sample, wherein the region includes a first portion including a buried structure and a second portion;
determining a difference in a parameter of secondary charged particles emitted from the first portion and the second portion; and
determining a first range in which the parameter is optimized.
12. The method of clause 11, wherein the parameter includes yield.
13. The method of clause 11, wherein the secondary charged particles include backscattered electrons emitted from the sample due to interaction of the primary charged particle beam with the region.
14. The method of clause 11, wherein the first range includes an energy range where the parameter is maximized
15. The method of clause 11, wherein the first range is between a first energy level and a second energy level.
16. The method of clause 11, further comprising:
adjusting a landing energy of the primary charged particle beam; and
determining a second range in which the parameter is optimized at the adjusted landing energy.
17. The method of clause 16, wherein the landing energy is determined based on requirements for signal strength and resolution.
18. The method of clause 17, wherein the requirements are defined by a user.
19. A charged particle beam system comprising:
a charged particle beam source configured to project a charged particle beam on a sample;
a detector configured to collect secondary charged particles; and
a controller configured to form an image based on received secondary charged particles that have an energy within a first range.
20. The system of clause 19, wherein the first range is determined based on a correlation between energy levels of received secondary charged particles and depth of penetration of the primary charged particles into the sample.
21. The system of clause 20, wherein the first range is determined such that only secondary charged particles with a penetration depth below a first threshold are used to form the image.
22. The system of clause 19, wherein the primary charged particles are electrons.
23. The system of clause 19, wherein the secondary charged particles are backscattered electrons.
24. The system of clause 19, wherein the controller is further configured to:
perform energy filtering, wherein the energy filtering includes using signals from the secondary charged particles that have the energy within the first range.
25. The system of clause 24, wherein the energy filtering includes discarding signals from the secondary charged particles that have an energy outside the first range.
26. The system of clause 24, further comprising an energy filter, wherein the controller is further configured to:
divert or immobilize secondary charged particles that have an energy outside the first range using the energy filter.
27. The system of clause 19, wherein the controller is further configured to: adjust a landing energy of the primary charged particles based on a depth of a buried structure in the sample.
28. The system of clause 27, wherein the landing energy is adjusted so that an effective depth and an effective spot size of an interaction region formed by the primary charged particles is matched to the buried structure.
29. A charged particle beam system comprising:
a charged particle beam source configured to project a charged particle beam on a sample;
a detector configured to collect secondary charged particles; and
a controller configured to perform a method of determining imaging conditions for charged particle beam imaging, the method comprising:
scanning a primary charged particle beam across a region of a sample, wherein the region includes a first portion including a buried structure and a second portion;
determining a difference in a parameter of secondary charged particles emitted from the first portion and the second portion; and
determining a first range in which the parameter is optimized.
30. The system of clause 29, wherein the parameter includes yield.
31. The system of clause 29, wherein the secondary charged particles include backscattered electrons emitted from the sample due to interaction of the primary charged particle beam with the region.
32. The system of clause 29, wherein the first range includes an energy range where the parameter is maximized.
33. The system of clause 29, wherein the first range is between a first energy level and a second energy level.
34. The system of clause 29, wherein the method further comprises:
adjusting a landing energy of the primary charged particle beam; and
determining a second range in which the parameter is optimized at the adjusted landing energy.
35. The system of clause 34, wherein the landing energy is determined based on requirements for signal strength and resolution.
36. The system of clause 35, wherein the requirements are defined by a user.
37. A non-transitory computer-readable medium storing a set of instructions that are executable by one or more processors of a charged particle beam apparatus to cause the charged particle beam apparatus to perform a method comprising:
emitting primary charged particles from a source;
receiving a plurality of secondary charged particles from a sample; and
forming an image based on received secondary charged particles that have an energy within a first range.
38. The medium of clause 37, wherein the first range is determined based on a correlation between energy levels of received secondary charged particles and depth of penetration of the primary charged particles into the sample.
39. The medium of clause 38, wherein the first range is determined such that only secondary charged particles with a penetration depth below a first threshold are used to form the image.
40. The medium of clause 37, wherein the primary charged particles are electrons.
41. The medium of clause 37, wherein the secondary charged particles are backscattered electrons.
42. The medium of clause 37, wherein the set of instructions are executable to cause the charged particle beam apparatus to:
perform energy filtering, wherein the energy filtering includes using signals from the secondary charged particles that have the energy within the first range.
43. The medium of clause 42, wherein the energy filtering includes discarding signals from the secondary charged particles that have an energy outside the first range.
44. The medium of clause 42, wherein the set of instructions are executable to cause the charged particle beam apparatus to:
divert or immobilize secondary charged particles that have an energy outside the first range using an energy filter.
45. The medium of clause 37, wherein the set of instructions are executable to cause the charged particle beam apparatus to:
adjust a landing energy of the primary charged particles based on a depth of a buried structure.
46. The medium of clause 45, wherein the landing energy is adjusted so that an effective depth and an effective spot size of an interaction region formed by the primary charged particles is matched to the buried structure.
47. A non-transitory computer-readable medium storing a set of instructions that are executable by one or more processors of a charged particle beam apparatus to cause the charged particle beam apparatus to perform a method comprising:
scanning a primary charged particle beam across a region of a sample, wherein the region includes a first portion including a buried structure and a second portion;
determining a difference in a parameter of secondary charged particles emitted from the first portion and the second portion; and
determining a first range in which the parameter is optimized.
48. The medium of clause 47, wherein the parameter includes yield.
49. The medium of clause 47, wherein the secondary charged particles include backscattered electrons emitted from the sample due to interaction of the primary charged particle beam with the region.
50. The medium of clause 47, wherein the first range includes an energy range where the parameter is maximized
51. The medium of clause 47, wherein the first range is between a first energy level and a second energy level.
52. The medium of clause 47, wherein the set of instructions are executable to cause the charged particle beam apparatus to:
adjust a landing energy of the primary charged particle beam; and
determine a second range in which the parameter is optimized at the adjusted landing energy.
53. The medium of clause 52, wherein the landing energy is determined based on requirements for signal strength and resolution.
54. The medium of clause 53, wherein the requirements are defined by a user.

It will be appreciated that the embodiments of the present disclosure are not limited to the exact construction that has been described above and illustrated in the accompanying drawings, and that various modifications and changes can be made without departing from the scope thereof.

1. A charged particle beam system comprising:
a charged particle beam source configured to project a charged particle beam on a sample;
a detector configured to collect secondary charged particles; and
a controller configured to form an image based on received secondary charged particles that have an energy within a first range.

2. The system of claim 1, wherein the first range is determined based on a correlation between energy levels of received secondary charged particles and depth of penetration of the primary charged particles into the sample.

3. The system of claim 2, wherein the first range is determined such that only secondary charged particles with a penetration depth below a first threshold are used to form the image.

4. The system of claim 1, wherein the primary charged particles are electrons.

5. The system of claim 1, wherein the secondary charged particles are backscattered electrons.

6. The system of claim 1, wherein the controller is further configured to:
perform energy filtering, wherein the energy filtering includes using signals from the secondary charged particles that have the energy within the first range.

7. The system of claim 6, wherein the energy filtering includes discarding signals from the secondary charged particles that have an energy outside the first range.

8. The system of claim 6, further comprising an energy filter, wherein the controller is further configured to:
divert or immobilize secondary charged particles that have an energy outside the first range using the energy filter.

9. The system of claim 1, wherein the controller is further configured to:
adjust a landing energy of the primary charged particles based on a depth of a buried structure in the sample.

10. The system of claim 9, wherein the landing energy is adjusted so that an effective depth and an effective spot size of an interaction region formed by the primary charged particles is matched to the buried structure.

11. A non-transitory computer-readable medium storing a set of instructions that are executable by one or more processors of a charged particle beam apparatus to cause the charged particle beam apparatus to perform a method comprising:
emitting primary charged particles from a source;
receiving a plurality of secondary charged particles from a sample; and
forming an image based on received secondary charged particles that have an energy within a first range.

12. The medium of claim 11, wherein the first range is determined based on a correlation between energy levels of received secondary charged particles and depth of penetration of the primary charged particles into the sample.

13. The medium of claim 12, wherein the first range is determined such that only secondary charged particles with a penetration depth below a first threshold are used to form the image.

14. The medium of claim 11, wherein the primary charged particles are electrons.

15. The medium of claim 11, wherein the secondary charged particles are backscattered electrons.
